(19) United States
(12) Patent Application Publication
(10) Pub. No.: US 2004/0084197 A1
(43) Pub. Date: May 6, 2004

(54) Process for making polyethylene laminate composites

(76) Inventor: Kent P. Bortz, Tucson, AZ (US)

Correspondence Address: QUARLES & BRADY STREICH LANG, LLP, ONE SOUTH CHURCH AVENUE, SUITE 1700, TUCSON, AZ, 85701-1621, US

(21) Appl. No.: 10/286,274

(22) Filed: Nov. 1, 2002

(51) Int. Cl. H05K 9/00; B32B 15/02; B32B 15/08; B32B 3/24; B32B 5/02; B32B 31/20

(52) U.S. Cl. 174/35 R; 156/309.6; 156/312; 442/16

(57) ABSTRACT

A polyethylene composite is manufactured by passing an inner core of fabric mesh sandwiched between two sheets of polyethylene material through a conventional set of high-pressure rollers at room temperature. The pressure exerted by the rollers on the polyethylene material causes its fluidification, so that each polyethylene layer permeates through the open mesh of the core material, bonds to the other layer and incorporates the core fibers to form a laminate composite. The thickness of the polyethylene sheets in relation to the gap and speed of the rollers has to be judiciously selected so that the pressure applied to the material is sufficient to fluidize the polyethylene at ambient temperature. Because no heat is applied to the system, the laminate composite is rapidly cooled as it passes through the rollers and requires no additional forming or processing.

### BACKGROUND OF THE INVENTION

1. Field of the Invention

This invention is related in general to the field of composite materials and, in particular, to an improved process for making a laminate polyethylene composite.

2. Description of the Related Art

Composite materials have gained much importance in various applications because of their strength, light weight, and adaptability to design variations that make them suitable for specialized applications. In particular, fiber-reinforced composites are being used routinely in the manufacture of roofing membranes, heavy-duty curtain materials, wrapping bands used to provide structural support to beams and columns, and protective liners for pools, ponds, and the like. Typically, these materials consist of a core of reinforcing material, often a fabric or other mesh, embedded in a protective polymeric coating.

All prior-art processes for manufacturing multilayer composites involve the steps of adhering one or more outer layers to the inner core using adhesives or other reactive components, or by melting the outer layers and causing them to penetrate and incorporate the core material. For example, U.S. Pat. No. 6,054,178 describes a process for reinforcing fabric mesh with outer layers of thermoplastic material. The fabric core is drawn into the gap between the rollers of a membrane extruder while molten thermoplastic material is deposited on each side of the fabric and passed through the rollers in molten form. The rollers force the molten material through the open mesh of the fabric, thereby causing the thermoplastic component to fuse around the inner-core mesh and form a monolithic structure.

The need to use chemical adhesives or heat to apply outer layers over an inner core has added to the cost and complexity of fabrication of laminate composites. In addition, the use of chemical adhesives as well as the process of heating a thermoplastic material to fluidize it and form it around an open mesh are typically accompanied by the release of noxious vapors. Therefore, any simplification in the conventional methods of manufacture would be a desirable advance in the art, especially if the undesirable aspects of prior-art processes are reduced. The present invention achieves such a result in the specific case of a composite consisting of a fabric mesh sandwiched between two polyethylene layers.

### BRIEF SUMMARY OF THE INVENTION

The primary objective of this invention is a process for fabricating laminate composites that does not require the use of chemicals or heat in order to bond outer layers to an inner mesh core.

Another goal is a process that is suitable for fabricating composites with a variety of core materials, including natural organic, synthetic and metallic fibers.

A final objective is a process that is suitable for implementation with equipment already in use in the manufacture of composite materials.

Therefore, according to these and other objectives, the present invention consists of passing an inner core of fabric mesh sandwiched between two sheets of polyethylene material through a conventional set of high-pressure rollers at room temperature. The pressure exerted by the rollers on the polyethylene material causes its fluidification, so that each polyethylene layer permeates through the open mesh of the core material, bonds to the other layer and incorporates the core fibers to form a laminate composite. The thickness of the polyethylene layers in relation to the gap and speed of the rollers has to be judiciously selected so that the pressure applied to the material is sufficient to fluidize the polyethylene sheets at ambient temperature. Because no heat is applied to the system, the laminate composite is rapidly cooled as it passes through the rollers and requires no additional forming or processing.

Various other purposes and advantages of the invention will become clear from its description in the specification that follows and from the novel features particularly pointed out in the appended claims. Therefore, to the accomplishment of the objectives described above, this invention consists of the features hereinafter illustrated in the drawings, fully described in the detailed description of the preferred embodiment and particularly pointed out in the claims. However, such drawings and description disclose but one of the various ways in which the invention may be practiced.

### BRIEF DESCRIPTION OF THE DRAWINGS

FIG. 1 is a schematic illustration of prior-art apparatus for manufacturing a fabric reinforced monolithic thermoplastic membrane using molten materials and a cooling element.

FIG. 2 is a schematic illustration of the equipment used to carry out the process of the invention.

FIG. 3 illustrates in cross-section the three-layer laminate composite produced by the process of the invention.

FIG. 4 is a block diagram of the steps involved in the practice of the invention.

FIG. 5 illustrates in partially cut-out view a material suitable for RF shields and RF curtains manufactured using a metal mesh and polyethylene to produce a laminate composite according to the invention.

### DESCRIPTION OF THE PREFERRED EMBODIMENTS OF THE INVENTION

The heart of the present invention lies in the realization that polyethylene can be fluidized at room temperature simply by the application of pressure, while all other known thermoplastic materials crack under similar conditions, a phenomenon known in the art as “crazing.” Accordingly, this property is advantageously exploited to simplify the process of making laminate composites.

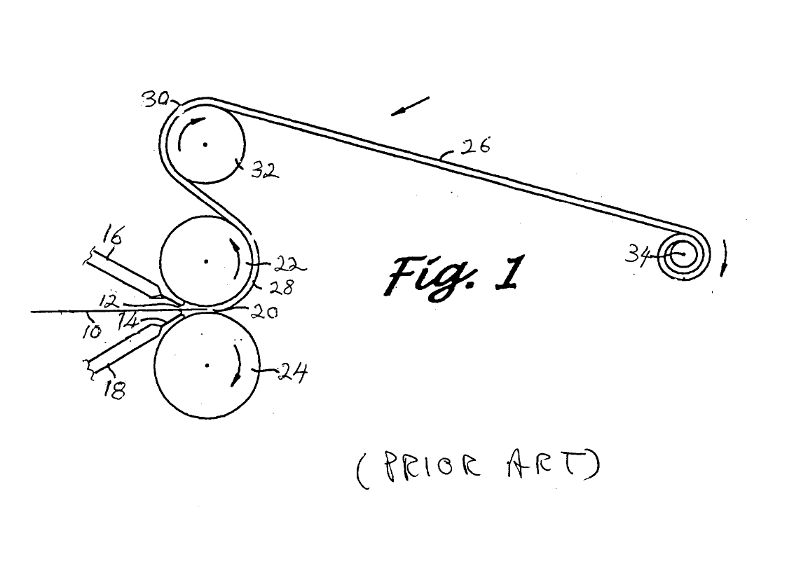

Referring to the drawings, wherein like parts are designated throughout with like numerals and symbols, FIG. 1 illustrates schematically the equipment used in a prior-art process for making laminate composites using thermoplastic material (disclosed in U.S. Pat. No. 6,054,178). A conventional membrane extruder is used to sandwich and bond a fabric-mesh inner core 10 between two layers of thermoplastic material 12,14. This material, consisting preferably of a polypropylene-based olefin, is melted and extruded from two nozzles 16,18 on each side of the core 10 as the core is drawn through the gap 20 between two rollers 22,24. Thus, the molten thermoplastic material is forced through the open mesh from both sides of the core 10, thereby causing the two layers 12,14 to fuse together, encapsulate the core 10, and produce a laminate composite 26. The bottom roller 24 is cooled with water, so that the bottom side 28 of the composite 26 begins to cool as it passes through the rollers. The top side 30 of the composite is cooled by a third roller 32 prior to final cooling of the product by exposure to ambient air and winding on a take-up roller 34 for transportation and storage.

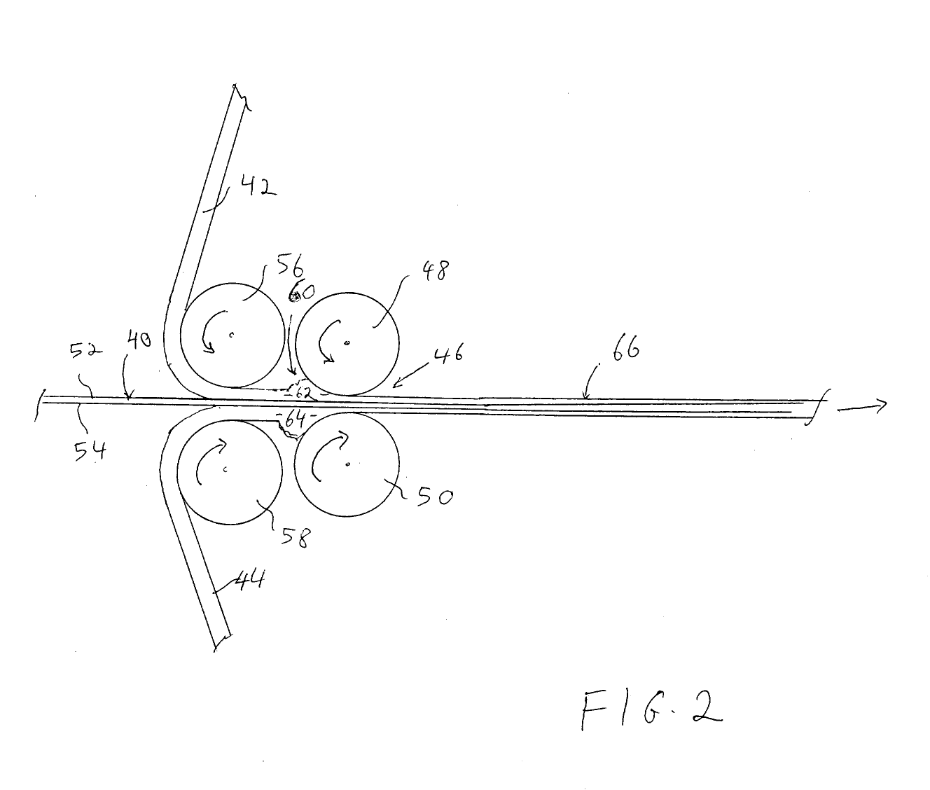

As illustrated in FIG. 2, the present invention simplifies the prior-art process and apparatus by eliminating the steps of heating and cooling the thermoplastic material. This is accomplished by the use of polyethylene, which is critical to the invention. While all forms of polyethylene (high, low and medium density, as these terms are commonly used in the art) have been found to be acceptable for fluidification under pressure, in practice, in addition its ability to avoid crazing while undergoing glass transition, high-density polyethylene yields a better product because of its higher abrasion resistance. Therefore, high-density polyethylene is most suitable and preferred to carry out the invention.

Thus, a polyethylene/fabric-mesh laminate composite can be fabricated simply by passing an inner core 40 made of fabric mesh or other web material sandwiched between two layers 42,44 of polyethylene through the gap 46 of conventional pressing members such as rollers 48 and 50. The polyethylene layers are deposited over each side 52,54 of the core 40 to form an aligned three-layer structure, preferably using two positioning rollers 56,58 placed in the vicinity of the throat 60 of the rollers 48,50. The rollers 56,58 are provided to remove air pockets from the interfaces between the inner core 40 and the outer polyethylene layers 42,44 and to align all layers with the rollers 48,50. Thus, the three layers 40,42,44 are easily engaged by the throat of the rollers 48,50 as they turn to move the material forward and the polyethylene layers are squeezed by the narrow gap 46. In relation to the thickness of the polyethylene and core layers, the gap 46 must be sufficiently small to provide a pressure sufficiently high to cause the polyethylene material to undergo glass transition. For most high-density polyethylenes, this pressure is about 310 psi, but lower pressures may be sufficient as a function of the amount of plasticizers used in the manufacture of the polyethylene. Lower pressures are similarly sufficient for lower-density polyethylenes. For example, low-density polyethylenes reach glass transition at about 90 psi. This pressure causes each outer layer 42,46 to melt under ambient conditions and form pools 62,64 of fluidized polyethylene ahead of the rollers 48,50. This semi-molten material penetrates from each side through the open mesh of the core 40 and fuses with the polyethylene material on the other side, just as would occur if the thermoplastic material had been heated. Operating at room temperature, the resulting laminate composite 66 produced as the material passes through the rollers is sufficiently solidified to require no further treatment. Thus, the composite 66 can be spooled onto a take-up roller (not shown) for further disposition.

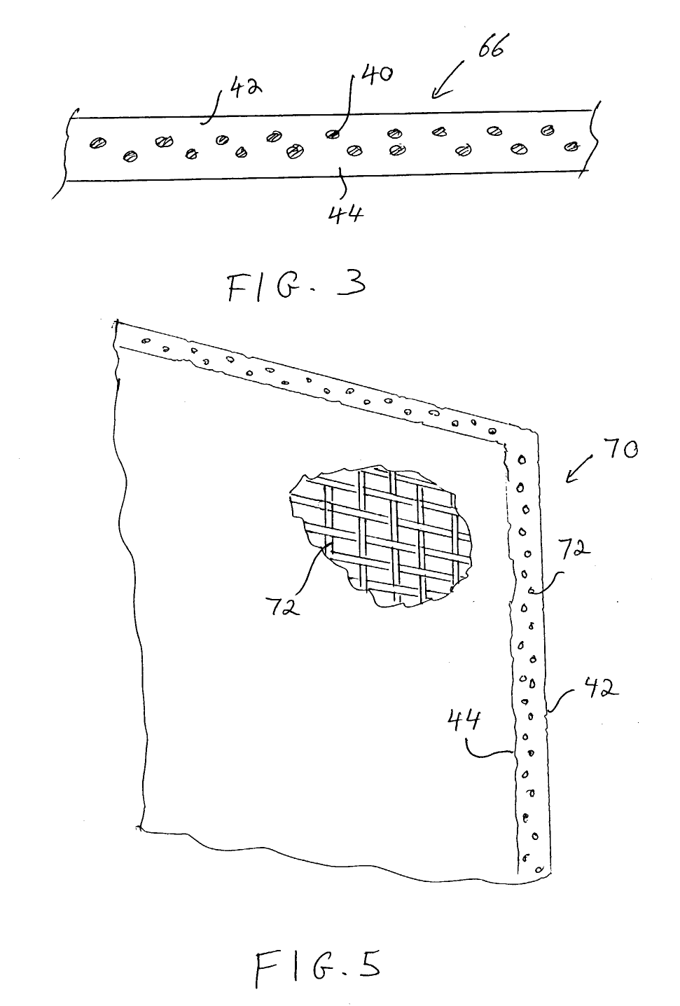

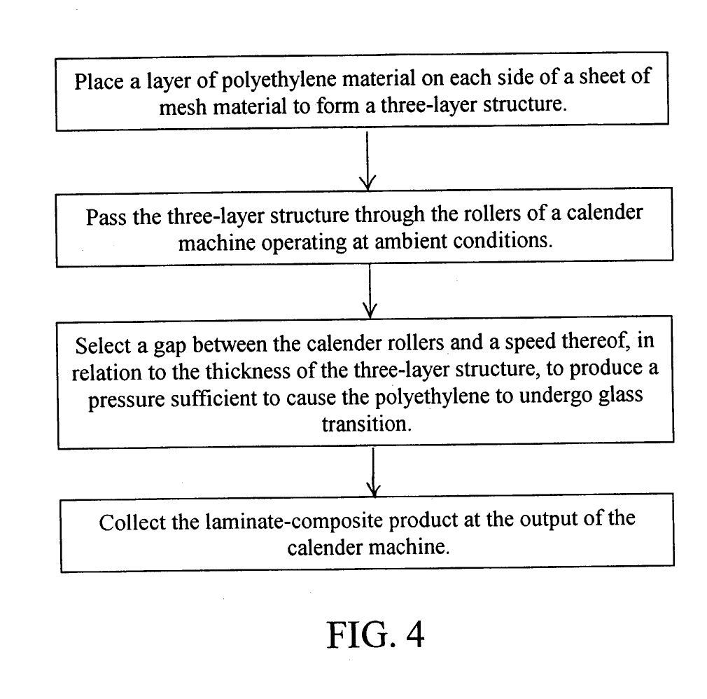

FIG. 3 illustrates in cross-section the three-layer laminate composite produced by the process of the invention. FIG. 4 is a block diagram of the steps involved in the practice of the invention. While the only laminating material suitable to practice the invention is polyethylene, it is understood that the inner core 40 may consist of any fabric or fiber capable of being permeated and encapsulated with fluidized material. Thus, any conventional web material, from natural or synthetic fabric to metal mesh, can be used in equivalent fashion.

Notably, metal-mesh materials can be easily and inexpensively encapsulated using the process of the invention. Metal mesh is commonly used to form metal Faraday cages and metal curtains that provide RF shielding to electronic equipment and to assembly lines. These applications typically utilize metallic structures that are relatively expensive to manufacture to achieve the required rigidity and abrasion resistance. The present invention provides an inexpensive and durable alternative by replacing the metal mesh used in RF shields and RF curtains with a laminate composite manufactured as described herein with a metal-mesh core, which may be of lower and less expensive quality, laminated on both sides with polyethylene. Such RF-shield cage and/or curtain composite material 70 is illustrated in FIG. 5, where the metal-mesh shield 72 is shown laminated within opposite polyethylene layers 42,44.

Similarly, Kevlar® could be used as the core 40 of the invention to manufacture a bullet-proof composite material that cannot be easily penetrated by a slow-moving piercing object (such as a knife). Kevlar® by itself is well known for its great strength and fabrics made with it prevent penetration by high-velocity projectiles, but are also known for being relatively easily pierced by a knife. The addition of two outer layers of polyethylene, which is a high-density and high-abrasion-resistance material, would provide an excellent composite for total protection in applications such as bullet-proof shields and vests.

Thus, this invention provides a simplified approach to the manufacture of a particular class of laminate composites. It has been demonstrated that any three-layer composite that consists of an inner-core mesh laminated with polyethylene can be produced at ambient conditions without the use of extrusion, heating, cooling, or chemicals.

Various changes in the details, steps and components that have been described may be made by those skilled in the art within the principles and scope of the invention herein illustrated and defined in the appended claims. For example, while it has been described in terms of a continuous process, the invention could be carried out in batch operation using static pressing members. Therefore, while the present invention has been shown and described herein in what is believed to be the most practical and preferred embodiments, it is recognized that departures can be made therefrom within the scope of the invention, which is not to be limited to the details disclosed herein but is to be accorded the full scope of the claims so as to embrace any and all equivalent processes and products.

I claim:

1. A process for fabricating a polyethylene laminate composite comprising the steps of:
providing a web of core material;
placing a layer of polyethylene material on each side of the core material to form a three-layer structure;
passing the three-layer structure through two pressing members under conditions that produce a pressure sufficiently high to cause the polyethylene material to undergo glass transition;
wherein the process is carried out at ambient operating conditions in the absence of heating, cooling, and extruding.

2. The process of claim 1, wherein said polyethylene material is a high-density polyethylene.

3. The process of claim 1, wherein said core material is a metallic mesh.

4. The process of claim 2, wherein said core material is a metallic mesh.

5. The process of claim 2, wherein said pressure is at least about 310 psi.

6. The process of claim 4, wherein said pressure is at least about 310 psi.

7. An RF cage manufactured with a laminate composite obtained with the process of claim 3.

8. An RF cage manufactured with a laminate composite obtained with the process of claim 4.

9. An RF curtain manufactured with a laminate composite obtained with the process of claim 3.

10. An RF curtain manufactured with a laminate composite obtained with the process of claim 4.
